(19) United States
(12) Patent Application Publication
(10) Pub. No.: US 2025/0286518 A1
(43) Pub. Date: Sep. 11, 2025

(54) ESD Protection Circuit

(71) Applicant: pSemi Corporation, San Diego, CA (US)

(72) Inventors: Jing Li, II, San Diego, CA (US); Xiaoling Guo, Austin, TX (US); Sivakumar Ganesan, Austin, TX (US)

(21) Appl. No.: 18/601,465

(22) Filed: Mar. 11, 2024

(51) Int. Cl. H03F 1/52

(52) U.S. Cl. CPC H03F 1/523; H03F 2200/165; H03F 2200/294

(57) ABSTRACT

Circuits and methods for providing ESD protection, particularly for LNAs lacking a DC blocking input capacitor (“capless LNAs”). Novel circuitry provides both improved ESD protection and an improved Noise Figure compared to conventional designs. One embodiment includes an integrated circuit including a voltage source pin and a plurality of low-noise amplifiers lacking a respective DC blocking input capacitor, each of the plurality of low-noise amplifiers including: a voltage source terminal coupled to the voltage source pin, an input terminal configured to receive a signal to be amplified, an output terminal configured to output an amplified version of the received signal to be amplified, an ESD protection circuit coupled to the input terminal and to both the voltage source terminal and a reference potential, and a distributed ESD clamp coupled between the reference potential and a node located between the ESD protection circuit and the voltage source terminal.

### BACKGROUND

### (1) Technical Field

The invention relates to electronic circuits, and more particularly to electro-static discharge protection circuits.

### (2) Background

Many modern electronic systems include radio frequency (RF) receivers; examples include cellular telephones, personal computers, tablet computers, wireless network components, televisions, cable system “set top” boxes, and radar systems. Many RF receivers are paired with RF transmitters in the form of transceivers, which often are quite complex two-way radios. In some cases, RF transceivers are capable of transmitting and receiving across multiple frequencies in multiple bands.

Amplifiers are a common component in RF transmitters, receivers, and transceivers, and are frequently used for power amplification of transmitted RF signals and for low-noise amplification of received RF signals. For many RF systems, particularly those requiring low power and/or portability (e.g., cellular telephones, WiFi-connected computers, cameras, and other devices), it has become common to use complementary field-effect transistors (FETs) made using metal-oxide semiconductor (CMOS) fabrication technology to create low-cost, low-power integrated circuits (ICs). CMOS devices include bulk CMOS, silicon-on-insulator (SOI) CMOS, and silicon-on-sapphire (SOS) CMOS (SOS being a type of SOI fabrication technology).

Receiving an RF signal in many environments requires a high quality low-noise amplifier (LNA) as part of an RF “front end” (RFFE) receiver or transceiver chain of circuits. FIG. 1A is a simplified schematic diagram of a prior art LNA circuit 100. In the illustrated example, the LNA circuit 100 includes an amplifier core 102 comprising a stack of two series-connected FETs: a common-source FET M_{CS} and a common-gate FET M_{CG} coupled in a cascode arrangement. An optional FET stack 104 may be coupled to the drain of the M_{CG} FET to handle high voltages. An RF input signal applied to an RF input terminal RF_{IN} is coupled through an impedance matching inductor L_{IN} and a DC blocking capacitor C_{IN} to the control gate of the common-source FET M_{CS}, which may be regarded as an input port INT of the amplification core 102.

The source of the common-source FET M_{CS} may be regarded as a degeneration port DT of the amplification core 102. A degeneration inductor L_{DG} is coupled between the degeneration port DT of the amplification core 102 and a reference potential, such as circuit ground.

The source of the common-gate FET M_{CG} is connected to the drain of the common-source FET M_{CS}. The drain of the common-gate FET M_{CG} provides an amplified RF output signal (directly or through the optional FET stack 104) at what may be regarded as an amplified-signal port AST of the amplification core 102. A CG Bias Generator circuit 106 may be included to provide a suitable bias voltage CG_V_{BIAS} to the common-gate FET M_{CG} and a CS Bias Generator circuit 108 may be included to provide a suitable bias voltage CS_V_{BIAS} to the common-source FET M_{CS}. In some embodiments, a single bias circuit may provide the bias voltages CG_V_{BIAS} and CS_V_{BIAS}.

In the illustrated example, the amplified-signal port AST is coupled to a voltage source terminal V_{DD} through a load module 110. In the illustrated example, the load module 110 includes a load inductor L_{LD} coupled in parallel with a de-queuing resistor R_{DQ}. The amplified-signal port AST is also coupled to an RF output terminal RF_{OUT} through a DC-blocking output capacitor COUT. The RF output terminal RF_{OUT} would typically be coupled to a 50-ohm load for many modern RF circuits.

Most or all of the components shown in FIG. 1A would be fabricated as part of an IC, such as a CMOS IC. Providing protection against electrostatic discharge (ESD) events is important in designing ICs that include FETs, which are notoriously susceptible to permanent damage when subjected to high voltages. For example, a human-body induced ESD event may reach 15,000 volts or more and have a short rise time, on the order of nanoseconds. Such an ESD event applied to an IC input pad or pin may cause damage to FETs within the IC (e.g., gate-oxide punch-through). Accordingly, ESD protection circuitry is generally needed to protect the IC circuitry.

In the example illustrated in FIG. 1A, an ESD clamp 112 is coupled between a reference potential (e.g., circuit ground) and a node X located between the impedance matching inductor L_{IN} and the DC blocking capacitor C_{IN}. FIG. 1B shows an example of a simple prior art ESD clamp 112. The example ESD clamp 112 comprises anti-parallel coupled diodes D1 and D2.

However, an ESD clamp 112 of the type shown in FIG. 1B is not suitable for some embodiments of LNAs. This invention addresses ESD protection for certain types of IC LNAs, particularly ICs that include multiple LNAs coupled to a common voltage source.

### SUMMARY

The present invention encompasses circuits and methods for providing ESD protection, particularly for LNAs lacking a DC blocking input capacitor (“capless LNAs”). Novel ESD circuitry provides both enhanced ESD protection and, in LNAs, improved Noise Figure compared to conventional designs.

One embodiment includes an integrated circuit including a voltage source pin and a plurality of low-noise amplifiers lacking a respective DC blocking input capacitor, each of the plurality of low-noise amplifiers including: a voltage source terminal coupled to the voltage source pin (usually an internal power supply), an input terminal configured to receive a signal to be amplified, an output terminal configured to output an amplified version of the signal to be amplified, an electro-static discharge protection circuit coupled to the input terminal and to both a voltage source terminal and a reference potential, and a distributed electro-static discharge clamp coupled between the reference potential and a node located between the electro-static discharge protection circuit and the voltage source terminal.

The electro-static discharge protection circuit may include a first diode having an anode coupled to the reference potential and a cathode coupled to the input terminal, and a second diode having an anode coupled to the input terminal and a cathode coupled to the voltage source terminal.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a simplified schematic diagram of a prior art LNA circuit.

FIG. 1B shows an example of a simple prior art ESD clamp.

FIG. 2A is a simplified schematic diagram of a novel LNA circuit with improved ESD protection circuitry in accordance with the present invention.

FIG. 2B is a block diagram of an IC that includes four LNA circuits of the type shown in FIG. 2A, each coupled to a single V_{DD} pin (or pad).

FIG. 3 is a schematic diagram of one embodiment of the distributed ESD clamp of FIG. 2B.

FIG. 4 is a graph of Noise Figure versus RF telecommunication bands A-K for an LNA module with a conventional ESD architecture (left bar for each band) and for an LNA module with an improved ESD architecture (right bar for each band) in accordance with the present invention.

FIG. 5 is a simplified schematic diagram of a variant LNA circuit with improved ESD circuitry in accordance with the present invention.

FIG. 6 is a top plan view of a substrate that may be, for example, a printed circuit board or chip module substrate (e.g., a thin-film tile).

FIG. 7 illustrates a prior art wireless communication environment comprising different wireless communication systems, and which may include one or more mobile wireless devices.

FIG. 8 is a block diagram of a transceiver that might be used in a wireless device, such as a cellular telephone, and which may beneficially incorporate an embodiment of the present invention for improved performance.

FIG. 9 is a process flow chart showing one method for protecting a plurality of low-noise amplifiers, fabricated as part of an integrated circuitry that includes a voltage source pin, from electro-static discharge events.

Like reference numbers and designations in the various drawings indicate like elements unless the context requires otherwise.

### DETAILED DESCRIPTION

The present invention encompasses circuits and methods for providing ESD protection, particularly for LNAs lacking a DC blocking input capacitor (“capless LNAs”). Novel ESD circuitry provides both enhanced ESD protection and, in LNAs, improved Noise Figure compared to conventional designs.

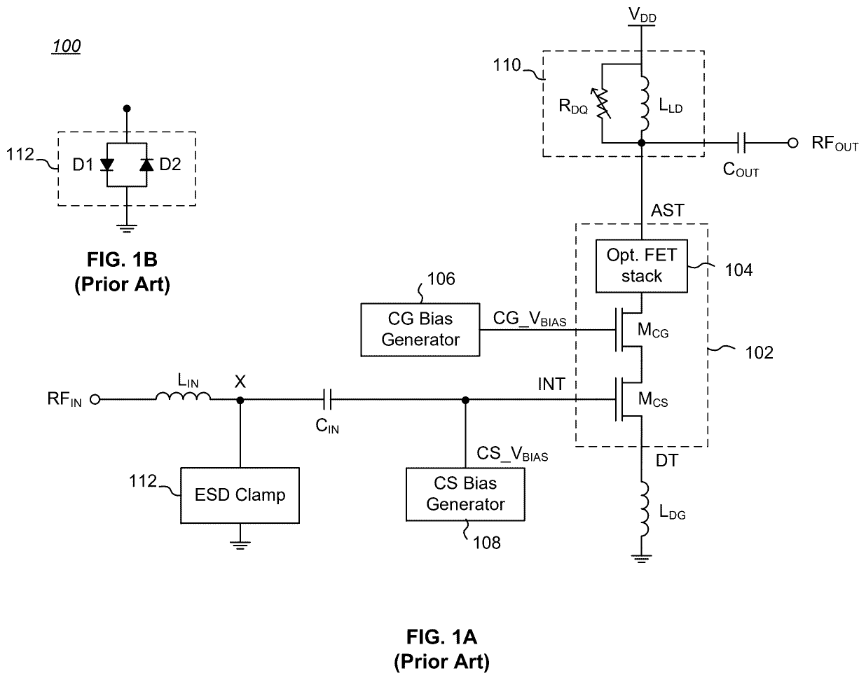

Referring to FIGS. 1A and 1B, the presence of the DC blocking capacitor C_{IN} ensures that the DC voltage at the RF input terminal RF_{IN} is zero. However, in capless LNAs, the absence of the DC blocking capacitor C_{IN} means that the input port INT of the amplification core is DC coupled to the input terminal of the LNA, and accordingly the DC voltage at RF_{IN} is not zero. Therefore, diode D1 in the ESD clamp 112 may leak current to ground at high temperatures which degrades the noise figure (NF) characteristic of the LNA. Such leakage may be reduced by adding another diode in series with diode D1, but the result is a worse third-order intercept point (IIP3), no improvement to the NF characteristic, and larger diodes to maintain an ESD performance similar to the ESD clamp 112 of FIG. 1B.

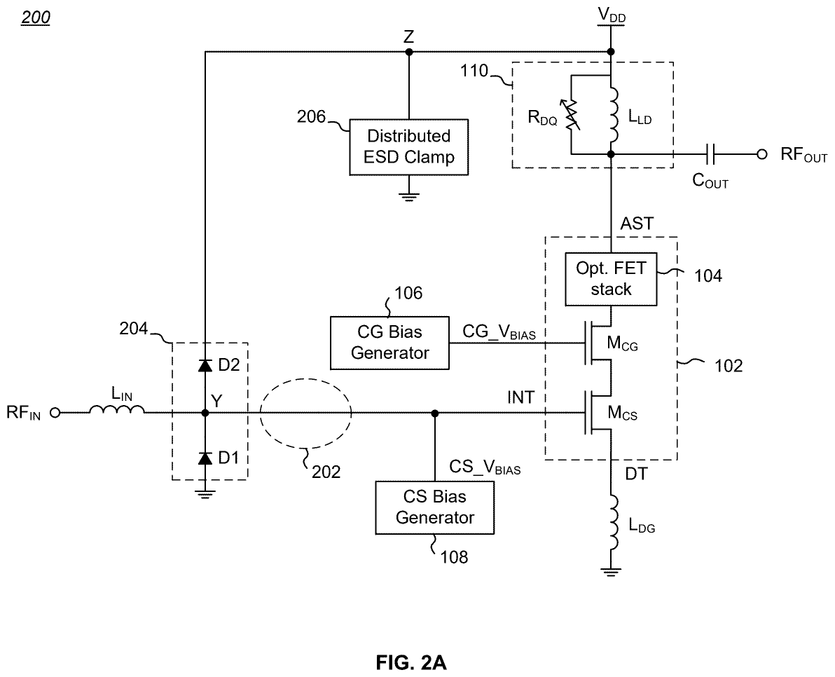

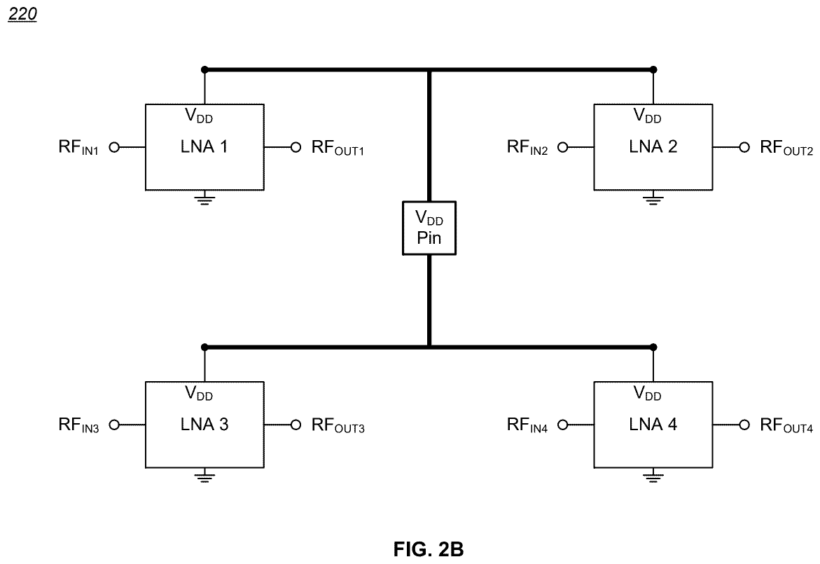

FIG. 2A is a simplified schematic diagram of a novel LNA circuit 200 with improved ESD protection circuitry in accordance with the present invention. Similar in many aspects to the LNA 100 of FIG. 1A, the novel LNA circuit 200 has three notable differences: first, the DC blocking capacitor C_{IN} is absent (indicated by the dashed oval 202), and thus the input port INT may receive a DC voltage; second, an ESD protection circuit 204 is coupled to a node Y located between the impedance matching inductor L_{IN} and the input port INT of the amplification core 102 and to both the voltage source terminal V_{DD} and a reference potential (e.g., circuit ground); and third, a distributed ESD clamp 206 coupled between the reference potential and a node Z located between the voltage source terminal V_{DD} and the ESD protection circuit 204. When the voltage source terminals are all connected, as shown in FIG. 2B, the distributed ESD clamp 206 and the ESD protection circuit 204 work together as a node of a network of distributed ESD protective circuitry.

The illustrated ESD protection circuit 204 is shown as comprising a first diode D1 having its anode coupled to the reference potential and its cathode coupled to node Y, and a second diode D2 having its anode coupled to node Y and its cathode coupled to the voltage source terminal V_{DD}. The ESD protection circuit will start conducting through diode D2 when diode D2 is forward biased or start conducting through diode D1 when diode D1 is forward biased. Because static electricity generally needs to be released quickly, a Schottky diode or a fast-switching diode is generally chosen for the diodes D1 and D2.

The RF series equivalent resistance associated with a diode depends on the voltage across the diode. When the voltage across a diode is greater than zero, the series resistance increases and makes a greater contribution to the total LNA noise. When the voltage across the diode is less than zero, the series resistance decreases and makes a lesser contribution to the total LNA noise. For a capless LNA, the voltages across both diodes D1 and D2 in the ESD protection circuit 204 are negative. Therefore, the ESD protection circuit 204 exhibits advantages in terms of LNA noise.

While addition of the ESD protection circuit 204 suffices when the V_{DD} pin of an IC is physically and electrically close to the voltage source terminal V_{DD} of the LNA 200, if the ESD protection circuit 204 needs to be connected to a distant V_{DD} pin, ESD performance will suffer due to the longer route. For example, FIG. 2B is a block diagram of an IC that includes four LNA circuits of the type shown in FIG. 2A, each coupled to a single V_{DD} pin (or pad). If an ESD event occurs for LNA 1, the ESD protection circuit 204 may need to release the static electricity over a long route to the V_{DD} pin.

Accordingly, embodiments of the present invention utilize a distributed ESD clamp 206 in combination with an ESD protection circuit 204 in each LNA so that static electricity affecting an LNA only needs to route no further than to the local distributed ESD clamp 206. As noted above, a distributed ESD clamp 206 is coupled between the reference potential and a node Z located between the local voltage source terminal V_{DD} and the ESD protection circuit 204 of each LNA 200. The local voltage source terminal V_{DD} is connected by internal IC routing lines to a V_{DD} pin, as shown in FIG. 2B. However, the location of the distributed ESD clamp 206 coupled to V_{DD} physically and electrically near the ESD protection circuit 204 significantly alleviates the problem of long V_{DD} routings.

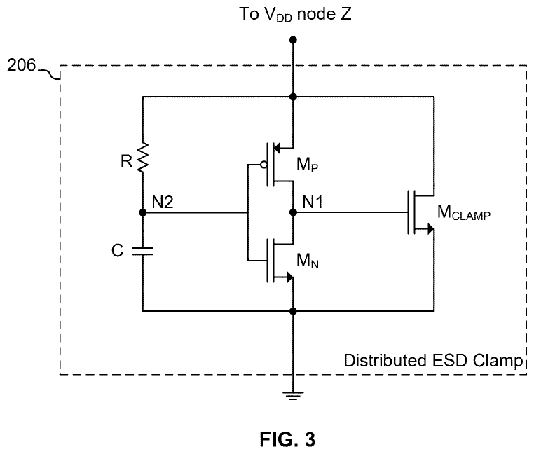

FIG. 3 is a schematic diagram of one embodiment of the distributed ESD clamp 206 of FIG. 2B. The conduction channels of a P-type FET (PFET) M_{P} and an N-type FET (NFET) M_{N} are coupled in series between node Z (located between the local voltage source terminal V_{DD} and the ESD protection circuit 204 in FIG. 2A) and a reference potential. A node N1 between M_{P} and M_{N} is coupled to the gate of an NFET M_{CLAMP}, the conduction channel of which is coupled between node Z and the reference potential. The respective gates of M_{P} and M_{N} are coupled to a node N2 between a resistor R coupled in series with a capacitor C between node Z and the reference potential. The resistor R and the capacitor C serve as slew rate detectors to detect fast voltage ramping during an ESD event. The output of the RC-based slew rate detector circuit at node N2 causes M_{P} and M_{N} to switch states, thus inverting the normally low voltage at node N1 to a higher voltage. The higher voltage at node N1 causes NFET M_{CLAMP} to turn ON, thus rapidly shunting the ESD current to local ground. As should be appreciated, other clamping circuits may also be used to implement the distributed ESD clamp 206.

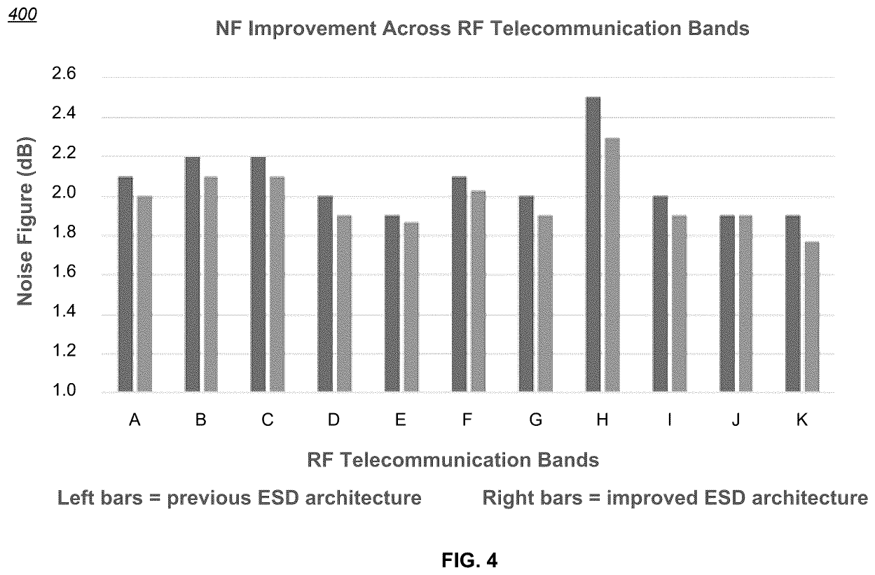

The improved ESD circuitry shown in FIG. 2A provides both improved ESD protection and an improved Noise Figure compared to other designs. For example, FIG. 4 is a graph 400 of Noise Figure versus RF telecommunication bands A-K for an LNA module with a conventional ESD architecture (left bar for each band) and for an LNA module with an improved ESD architecture (right bar for each band) in accordance with the present invention. Lower NF values are better. The LNA with improved ESD architecture averages about a 0.1 dB improvement in NF compared to the LNA with a conventional ESD architecture.

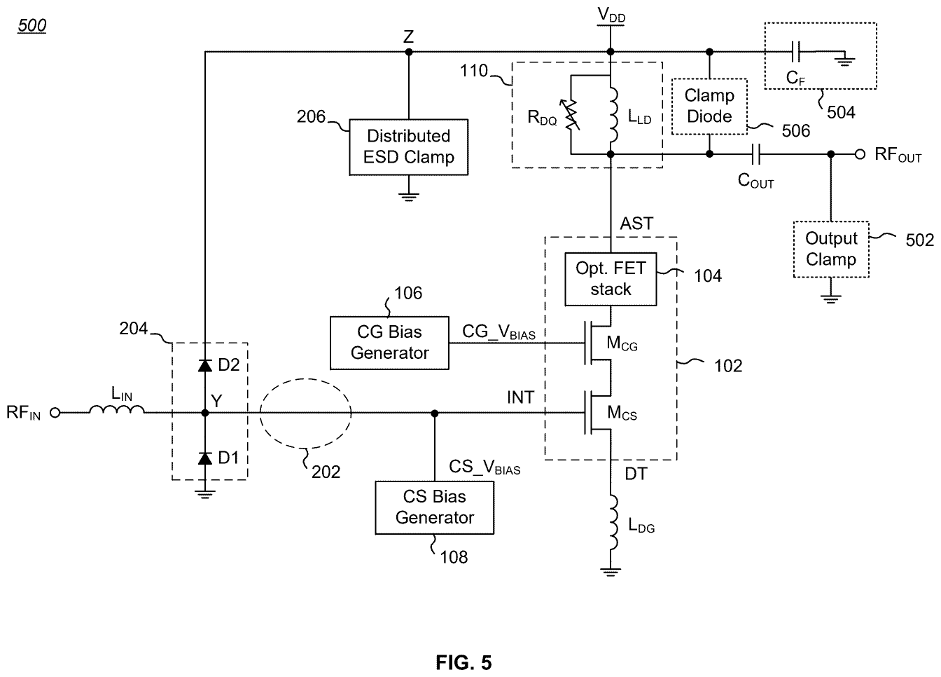

The LNA circuit 200 of FIG. 2A is a basic LNA architecture. As will be appreciated by one of ordinary skill in the art, a number of variant LNAs may beneficially include the ESD circuitry of the present invention. For example, additional control and configuration switches may be included, and the LNA 200 may include more than one amplifier core 102. FIG. 5 is a simplified schematic diagram of a variant LNA circuit 500 with improved ESD circuitry in accordance with the present invention. Similar in most aspects to the LNA 200 of FIG. 2A, the variant LNA circuit 500 includes (1) an output clamp 502 coupled between the output terminal RF_{OUT} and the reference potential to clamp transient signals, (2) a filter capacitor CF 504 coupled between the voltage source terminal V_{DD} and the reference potential to filter noise that may be present at that node, and (3) a clamp diode 506 coupled between the voltage source terminal V_{DD} and the amplified-signal port AST to reduce the voltage swing at the LNA output, which will benefits parameter specifications (e.g., output saturation power) that are required in many applications. In some variants, the bias voltages CG_V_{BIAS} and CS_V_{BIAS} may be variable, the degeneration inductor L_{DG} may be variable and/or bypassable, the load module 110 may include additional and/or more complex (e.g., variable and/or bypassable) LRC components, and feedback circuitry may be coupled between the amplified-signal port AST and the input port INT. Configuration switches (not shown) may be used to selectively connect or disconnect various circuit elements, for example, to accommodate different gain modes of operation.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

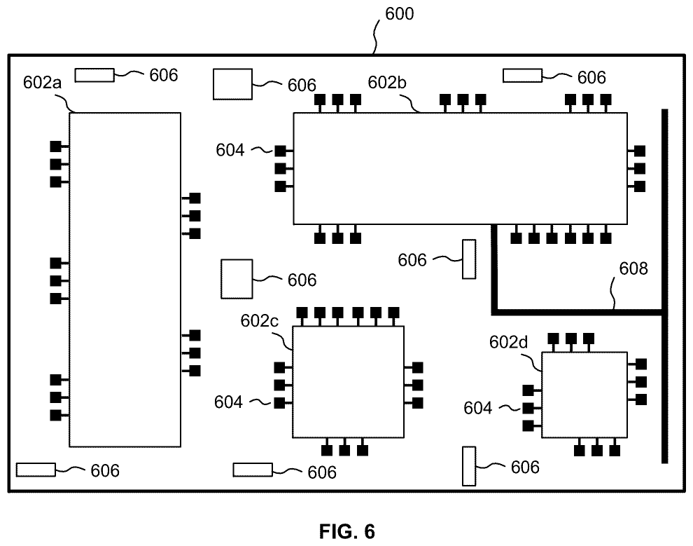

As one example of further integration of embodiments of the present invention with other components, FIG. 6 is a top plan view of a substrate 600 that may be, for example, a printed circuit board or chip module substrate (e.g., a thin-film tile). In the illustrated example, the substrate 600 includes multiple ICs 602a-602d having terminal pads 604 which would be interconnected by conductive vias and/or traces on and/or within the substrate 600 or on the opposite (back) surface of the substrate 600 (to avoid clutter, the surface conductive traces are not shown and not all terminal pads are labelled). The ICs 602a-602d may embody, for example, signal switches, active and/or passive filters, amplifiers (including one or more LNAs), and other circuitry. For example, IC 602b may incorporate one or more instances of an LNA like the LNAs 200, 500 shown in FIGS. 2A and 5.

The substrate 600 may also include one or more passive devices 606 embedded in, formed on, and/or affixed to the substrate 600. While shown as generic rectangles, the passive devices 606 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 600 to other passive devices 606 and/or the individual ICs 602a-602d.

The front or back surface of the substrate 600 may be used as a location for the formation of other structures. For example, one or more antennae may be formed on or affixed to the front or back surface of the substrate 600; one example of a front-surface antenna 608 is shown, coupled to an IC die 602b, which may include RF front-end circuitry. Thus, by including one or more antennae on the substrate 600, a complete radio may be created.

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

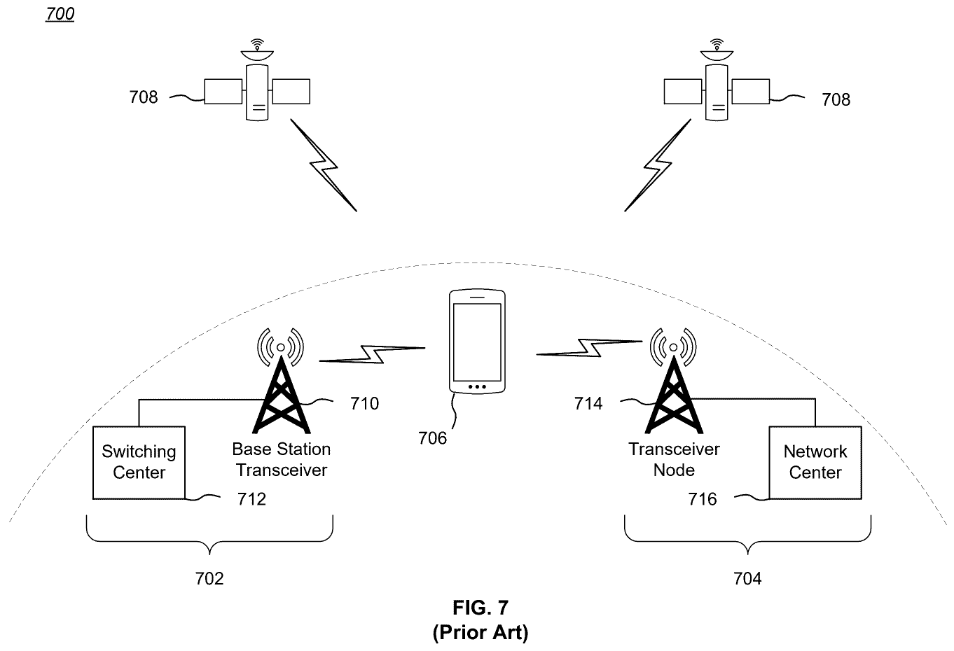

As an example of wireless RF system usage, FIG. 7 illustrates a prior art wireless communication environment 700 comprising different wireless communication systems 702 and 704, and which may include one or more mobile wireless devices 706. A wireless device 706 may be a cellular phone, a wireless-enabled computer or tablet, or some other wireless communication unit or device. A wireless device 706 may also be referred to as a mobile station, user equipment, an access terminal, or some other terminology known in the telecommunications industry.

A wireless device 706 may be capable of communicating with multiple wireless communication systems 702, 704 using one or more of telecommunication protocols such as the protocols noted above. A wireless device 706 also may be capable of communicating with one or more satellites 708, such as navigation satellites (e.g., GPS) and/or telecommunication satellites. The wireless device 706 may be equipped with multiple antennas, externally and/or internally, for operation on different frequencies and/or to provide diversity against deleterious path effects such as fading and multi-path interference.

The wireless communication system 702 may be, for example, a CDMA-based system that includes one or more base station transceivers (BSTs) 710 and at least one switching center (SC) 712. Each BST 710 provides over-the-air RF communication for wireless devices 706 within its coverage area. The SC 712 couples to one or more BSTs 710 in the wireless system 702 and provides coordination and control for those BSTs 710.

The wireless communication system 704 may be, for example, a TDMA-based system that includes one or more transceiver nodes 714 and a network center (NC) 716. Each transceiver node 714 provides over-the-air RF communication for wireless devices 706 within its coverage area. The NC 716 couples to one or more transceiver nodes 714 in the wireless system 704 and provides coordination and control for those transceiver nodes 714.

In general, each BST 710 and transceiver node 714 is a fixed station that provides communication coverage for wireless devices 706, and may also be referred to as base stations or some other terminology known in the telecommunications industry. The SC 712 and the NC 716 are network entities that provide coordination and control for the base stations and may also be referred to by other terminologies known in the telecommunications industry.

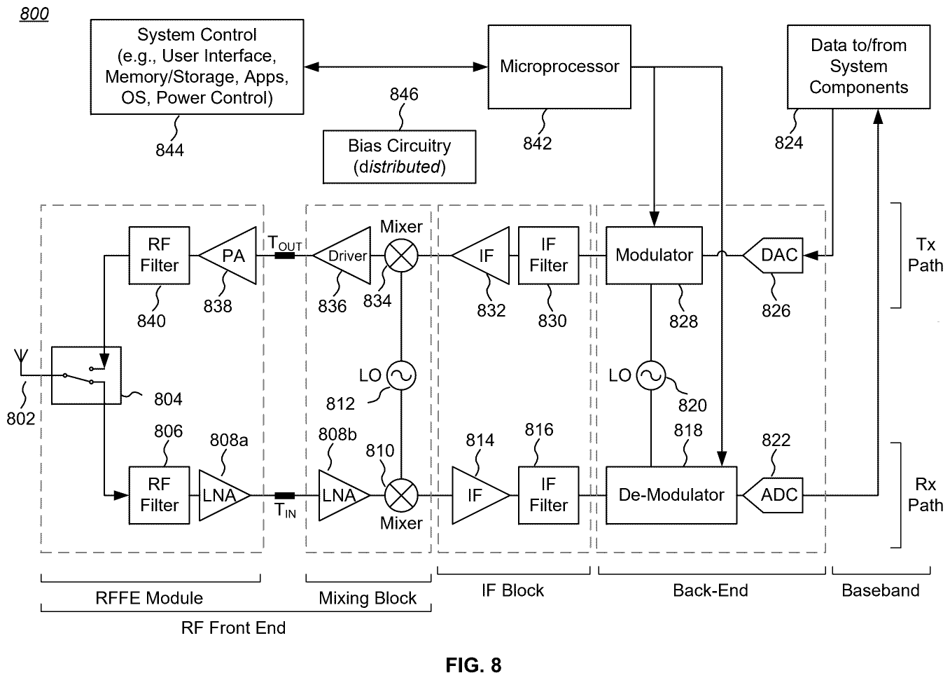

An important aspect of any wireless system, including the systems shown in FIG. 7, is in the details of how the component elements of the system perform. FIG. 8 is a block diagram of a transceiver 800 that might be used in a wireless device, such as a cellular telephone, and which may beneficially incorporate an embodiment of the present invention for improved performance. As illustrated, the transceiver 800 includes a mix of RF analog circuitry for directly conveying and/or transforming signals on an RF signal path, non-RF analog circuitry for operational needs outside of the RF signal path (e.g., for bias voltages and switching signals), and digital circuitry for control and user interface requirements. In this example, a receiver path Rx includes RF Front End (RFFE), Intermediate Frequency (IF) Block, Back-End, and Baseband sections (noting that in some implementations, the differentiation between sections may be different). The various illustrated sections and circuit elements may be embodied in one die or multiple IC dies. For example, the RF Front End in the illustrated example may include an RFFE module and a Mixing Block, which may be embodied in (or as part of) different IC dies or modules. The different dies and/or modules may be coupled by transmission lines T_{IN} and T_{OUT} (e.g., microstrips, co-planar waveguides, or an equivalent structure or circuit), either or both of which may have, for example, a 50Ω impedance.

The receiver path Rx receives over-the-air RF signals through at least one antenna 802 and a switching unit 804, which may be implemented with active switching devices (e.g., field effect transistors or FETs) and/or with passive devices that implement frequency-domain multiplexing, such as a diplexer or duplexer. An RF filter 806 passes desired received RF signals to at least one low noise amplifier (LNA) 808a, the output of which is coupled from the RFFE Module to at least one LNA 808b in the Mixing Block (through transmission line T_{IN} in this example). The LNA(s) 808b may provide buffering, input matching, and reverse isolation. In some embodiments, the LNA(s) 808a and 808b may be a single LNA. The LNA(s) 808a and 808b may include ESD protection circuitry in accordance with the present invention.

The output of the LNA(s) 808b is combined in a corresponding mixer 810 with the output of a first local oscillator 812 to produce an IF signal. The IF signal may be amplified by an IF amplifier 814 and subjected to an IF filter 816 before being applied to a demodulator 818, which may be coupled to a second local oscillator 820. The demodulated output of the demodulator 818 is transformed to a digital signal by an analog-to-digital converter 822 and provided to one or more system components 824 (e.g., a video graphics circuit, a sound circuit, memory devices, etc.). The converted digital signal may represent, for example, video or still images, sounds, or symbols, such as text or other characters.

In the illustrated example, a transmitter path Tx includes Baseband, Back-End, IF Block, and RF Front End sections (again, in some implementations, the differentiation between sections may be different). Digital data from one or more system components 824 is transformed to an analog signal by a digital-to-analog converter 826, the output of which is applied to a modulator 828, which also may be coupled to the second local oscillator 820. The modulated output of the modulator 828 may be subjected to an IF filter 830 before being amplified by an IF amplifier 832. The output of the IF amplifier 832 is then combined in a mixer 834 with the output of the first local oscillator 812 to produce an RF signal. The RF signal may be amplified by a driver 836, the output of which is coupled to a power amplifier (PA) 838 (through transmission line T_{OUT} in this example). The amplified RF signal may be coupled to an RF filter 840, the output of which is coupled to at least one antenna 802 through the switching unit 804.

The operation of the transceiver 800 is controlled by a microprocessor 842 in known fashion, which interacts with system control components 844 (e.g., user interfaces, memory/storage devices, application programs, operating system software, power control, etc.). In addition, the transceiver 800 will generally include other circuitry, such as bias circuitry 846 (which may be distributed throughout the transceiver 800 in proximity to transistor devices), electro-static discharge (ESD) protection circuits, testing circuits (not shown), factory programming interfaces (not shown), etc.

In modern transceivers, there are often more than one receiver path Rx and transmitter path Tx, for example, to accommodate multiple frequencies and/or signaling modalities. Further, as should be apparent to one of ordinary skill in the art, some components of the transceiver 800 may be positioned in a different order (e.g., filters) or omitted. Other components can be (and often are) added, such as (by way of example only) additional filters, impedance matching networks, variable phase shifters/attenuators, power dividers, etc.

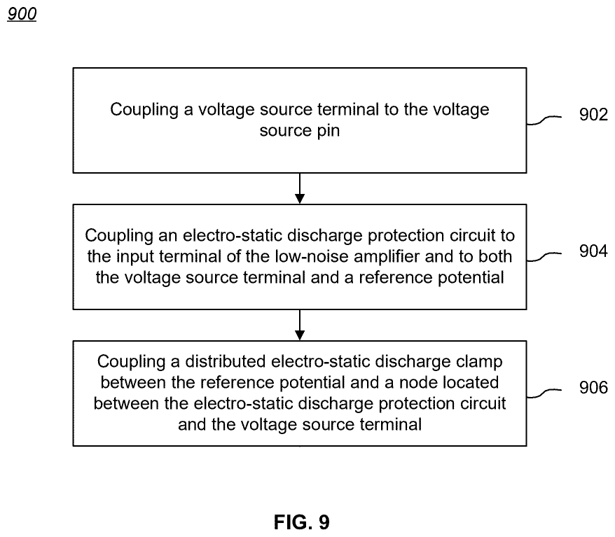

Another aspect of the invention includes corresponding methods for protecting low-noise amplifiers from electro-static discharge events. For example, FIG. 9 is a process flow chart 900 showing one method for protecting a plurality of low-noise amplifiers, fabricated as part of an integrated circuitry that includes a voltage source pin, from electro-static discharge events. The method includes, for each low-noise amplifier: coupling a voltage source terminal to the voltage source pin (Block 902); coupling an electro-static discharge protection circuit to the input terminal of the low-noise amplifier and to both the voltage source terminal and a reference potential (Block 904); and coupling a distributed electro-static discharge clamp between the reference potential and a node located between the electro-static discharge protection circuit and the voltage source terminal (Block 906).

Additional aspects of the above method may include one or more of the following: wherein the electro-static discharge protection circuit includes a first diode having an anode coupled to the reference potential and a cathode coupled to the input terminal, and a second diode having an anode coupled to the input terminal and a cathode coupled to the voltage source terminal; and/or wherein the distributed electro-static discharge clamp includes a resistor coupled between a first internal node and the node located between the electro-static discharge protection circuit and the voltage source terminal, a capacitor coupled between the first internal node and the reference potential, a P-type FET having a conduction channel coupled between a second internal node and the node located between the electro-static discharge protection circuit and the voltage source terminal, and having a control gate coupled to the first internal node, a first N-type FET having a conduction channel coupled between the second internal node and the reference potential, and having a control gate coupled to the first internal node, and a second N-type FET having a conduction channel coupled between the reference potential and the node located between the electro-static discharge protection circuit and the voltage source terminal, and having a control gate coupled to the second internal node.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as bipolar junction transistors (BJTs), and BiCMOS, LDMOS, and FinFET devices. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

### CONCLUSION

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. An integrated circuit including a voltage source pin and a plurality of low-noise amplifiers lacking a respective DC blocking input capacitor, each of the plurality of low-noise amplifiers including:
(a) a voltage source terminal coupled to the voltage source pin;
(b) an input terminal configured to receive a signal to be amplified;
(c) an output terminal configured to output an amplified version of the signal to be amplified;
(d) an electro-static discharge protection circuit coupled to the input terminal and to both the voltage source terminal and a reference potential; and
(e) a distributed electro-static discharge clamp coupled between the reference potential and a node located between the electro-static discharge protection circuit and the voltage source terminal.

2. The integrated circuit of claim 1, wherein the electro-static discharge protection circuit includes:
(a) a first diode having an anode coupled to the reference potential and a cathode coupled to the input terminal; and
(b) a second diode having an anode coupled to the input terminal and a cathode coupled to the voltage source terminal.

3. The integrated circuit of claim 2, wherein the first and second diodes are each a Schottky diode or a fast-switching diode.

4. The integrated circuit of claim 1, wherein the distributed electro-static discharge clamp includes:
(a) a resistor coupled between a first internal node and the node located between the electro-static discharge protection circuit and the voltage source terminal;
(b) a capacitor coupled between the first internal node and the reference potential;
(c) a P-type FET having a conduction channel coupled between a second internal node and the node located between the electro-static discharge protection circuit and the voltage source terminal, and having a control gate coupled to the first internal node;
(d) a first N-type FET having a conduction channel coupled between the second internal node and the reference potential, and having a control gate coupled to the first internal node; and
(e) a second N-type FET having a conduction channel coupled between the reference potential and the node located between the electro-static discharge protection circuit and the voltage source terminal, and having a control gate coupled to the second internal node.

5. The integrated circuit of claim 1, wherein each low-noise amplifier further includes a filter capacitor coupled between the voltage source terminal and the reference potential.

6. The integrated circuit of claim 1, wherein each low-noise amplifier further includes an output clamp coupled between the output terminal and the reference potential.

7. An integrated circuit including a voltage source pin and a plurality of low-noise amplifiers, each of the plurality of low-noise amplifiers including:
(a) a voltage source terminal coupled to the voltage source pin;
(b) an input terminal configured to receive a signal to be amplified;
(c) an output terminal configured to output an amplified version of the signal to be amplified;
(d) at least one amplifier core each including an input port coupled to the input terminal and an amplified-signal port coupled to the output terminal;
(e) an electro-static discharge protection circuit coupled to the input port of the amplification core and to both the voltage source terminal and a reference potential; and
(f) a distributed electro-static discharge clamp coupled between the reference potential and a node located between the electro-static discharge protection circuit and the voltage source terminal.

8. The integrated circuit of claim 7, wherein the electro-static discharge protection circuit includes:
(a) a first diode having an anode coupled to the reference potential and a cathode coupled to the input port of the amplification core; and
(b) a second diode having an anode coupled to the input port of the amplification core and a cathode coupled to the voltage source terminal.

9. The integrated circuit of claim 8, wherein the first and second diodes are each a Schottky diode or a fast-switching diode.

10. The integrated circuit of claim 7, wherein the distributed electro-static discharge clamp includes:
(a) a resistor coupled between a first internal node and the node located between the electro-static discharge protection circuit and the voltage source terminal;
(b) a capacitor coupled between the first internal node and the reference potential;
(c) a P-type FET having a conduction channel coupled between a second internal node and the node located between the electro-static discharge protection circuit and the voltage source terminal, and having a control gate coupled to the first internal node;
(d) a first N-type FET having a conduction channel coupled between the second internal node and the reference potential, and having a control gate coupled to the first internal node; and
(e) a second N-type FET having a conduction channel coupled between the reference potential and the node located between the electro-static discharge protection circuit and the voltage source terminal, and having a control gate coupled to the second internal node.

11. The integrated circuit of claim 7, wherein each low-noise amplifier further includes a filter capacitor coupled between the voltage source terminal and the reference potential.

12. The integrated circuit of claim 7, wherein each low-noise amplifier further includes an output clamp coupled between the output terminal and the reference potential.

13. The integrated circuit of claim 7, wherein each low-noise amplifier further includes a clamp diode coupled between the voltage source terminal and the amplified-signal port.

14. An integrated circuit including a voltage source pin and a plurality of low-noise amplifiers lacking a respective DC blocking input capacitor, each of the plurality of low-noise amplifiers including:
(a) a voltage source terminal coupled to the voltage source pin;
(b) an input terminal configured to receive a signal to be amplified;
(c) an output terminal configured to output an amplified version of the signal to be amplified;
(d) at least one amplifier core each including an input port coupled to the input terminal and an amplified-signal port coupled to the output terminal;
(e) an electro-static discharge protection circuit including:
(1) a first diode having an anode coupled to a reference potential and a cathode coupled to the input port of the amplification core; and
(2) a second diode having an anode coupled to the input port of the amplification core and a cathode coupled to the voltage source terminal; and
(f) a distributed electro-static discharge clamp coupled between the reference potential and a node located between the electro-static discharge protection circuit and the voltage source terminal.

15. The integrated circuit of claim 14, wherein the first and second diodes are each a Schottky diode or a fast-switching diode.

16. The integrated circuit of claim 14, wherein the distributed electro-static discharge clamp includes:
(a) a resistor coupled between a first internal node and the node located between the electro-static discharge protection circuit and the voltage source terminal;
(b) a capacitor coupled between the first internal node and the reference potential;
(c) a P-type FET having a conduction channel coupled between a second internal node and the node located between the electro-static discharge protection circuit and the voltage source terminal, and having a control gate coupled to the first internal node;
(d) a first N-type FET having a conduction channel coupled between the second internal node and the reference potential, and having a control gate coupled to the first internal node; and
(e) a second N-type FET having a conduction channel coupled between the reference potential and the node located between the electro-static discharge protection circuit and the voltage source terminal, and having a control gate coupled to the second internal node.

17. The integrated circuit of claim 14, wherein each low-noise amplifier further includes a filter capacitor coupled between the voltage source terminal and the reference potential.

18. The integrated circuit of claim 14, wherein each low-noise amplifier further includes an output clamp coupled between the output terminal and the reference potential.

19. The integrated circuit of claim 14, wherein each low-noise amplifier further includes a clamp diode coupled between the voltage source terminal and the amplified-signal port.

20. A method of protecting a plurality of low-noise amplifiers, fabricated as part of an integrated circuitry that includes a voltage source pin, from electro-static discharge events, including, for each low-noise amplifier:
(a) coupling a voltage source terminal to the voltage source pin;
(b) coupling an electro-static discharge protection circuit to the input terminal of the low-noise amplifier and to both the voltage source terminal and a reference potential; and
(c) coupling a distributed electro-static discharge clamp between the reference potential and a node located between the electro-static discharge protection circuit and the voltage source terminal.
